(19) United States
(12) Patent Application Publication
(10) Pub. No.: US 2007/0148848 A1
(43) Pub. Date: Jun. 28, 2007

(54) METHODS OF FORMING DUAL GATE OF SEMICONDUCTOR DEVICE

(75) Inventors: Gyu Hyun Kim, Yongin-si (KR); Geun Min Choi, Icheon-si (KR); Baik II Choi, Seoul (KR); Dong Joo Kim, Busan (KR); Ji Hye Han, Incheon (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-shi (KR)

(21) Appl. No.: 11/614,975

(22) Filed: Dec. 22, 2006

(30) Foreign Application Priority Data
Dec. 22, 2005 (KR) 2005-128307
Sep. 13, 2006 (KR) 2006-88631

(51) Int. Cl. H01L 21/8238

(52) U.S. Cl. 438/199; 438/749; 438/906

(57) ABSTRACT

Disclosed herein is a method for forming a dual gate of a semiconductor device. The method comprises the steps of forming a first polysilicon layer doped with p-type impurity ions and a second polysilicon layer doped with n-type impurity ions on a first region and a second region of a semiconductor substrate, respectively, and sequentially subjecting the surfaces of the first and second polysilicon layers to first wet cleaning, second wet cleaning and dry cleaning.

### BACKGROUND OF THE INVENTION

The present invention relates to methods for fabricating a semiconductor device, and more specifically to methods for forming a dual gate consisting of a gate of p-conductivity type and a gate of n-conductivity type in a semiconductor device.

General complementary metal oxide semiconductor (CMOS) devices have a structure in which a pair of a p-channel type MOS transistor and an n-channel type MOS transistor is formed on one semiconductor substrate so that the transistors operate in a complementary manner. Since this structure of CMOS devices contributes to an increase in the overall efficiency and operating speed of the semiconductor devices, it is currently applied to logic devices and memory devices that require high speed and high performance. Gates of a PMOS transistor and an NMOS transistor in CMOS devices are doped with different conductivity types. This gate structure is called a “dual gate”.

A general method for forming the dual gate will be briefly explained below. First, a gate insulating layer is formed on a semiconductor substrate. Then, a gate conductive layer, e.g., a polysilicon layer, doped with n-type impurity ions is formed on the gate insulating layer. An ion implantation process is performed using a first photoresist pattern, through which a PMOS transistor region is exposed, to implant p-type impurity ions into the gate conductive layer within the PMOS transistor region. Next, an ion implantation process is performed using a second photoresist pattern, through which an NMOS transistor region is exposed, to implant n-type impurity ions into the gate conductive layer within the NMOS transistor region. Next, a diffusion process is performed to form gate conductive layers of n- and p-conductivity types, followed by cleaning and drying to remove a native oxide layer formed on the gate conductive layers of n- and p-conductivity types. A metal silicide layer and a gate hardmask layer are sequentially formed on the gate conductive layers of n- and p-conductivity types. Finally, the resulting structure is subjected to a common patterning process to form a dual gate wherein gate conductive layer patterns of p- and n-conductivity types are arranged within the NMOS and PMOS transistor regions, respectively.

According to the general method for forming a dual gate, stripping and cleaning are performed to remove the first and second photoresist patterns after the ion implantation processes for the implantation of n- and p-type impurity ions into the gate conductive layer. Specifically, the stripping is achieved by dry stripping using an oxygen (O₂) plasma. However, the photoresist patterns whose upper portions are hardened due to high concentration ion implantation are incompletely removed by dry stripping using an oxygen plasma, thus leaving photoresist residues behind. The photoresist residues are not readily removed in the subsequent cleaning and serve as obstacles in the normal implementation of the subsequent gate patterning process, causing many problems, e.g., short circuiting and bridging of gate lines. In a serious case, the gate conductive layers may remain unetched.

Before formation of the metal silicide layer, cleaning is performed to remove a native oxide layer in accordance with the following procedure. First, cleaning is performed using a sulfuric acid peroxide mixture (SPM) of H₂SO₄ and H₂O₂ (4:1) as a cleaning solution at 120° C. for about 10 minutes. Then, rinsing is performed using ultrapure water (UPW). Cleaning is further performed using Standard Clean-1 (SC-1), which is a mixture of NH₄OH, H₂O₂ and H₂O (1:4:20), as a cleaning solution at 25° C. for about 10 minutes. Subsequently, rinsing is again performed using ultrapure water (UPW). Finally, cleaning is performed using a buffered oxide echant (BOE) containing NH₄F as a cleaning solution for about 200 seconds, followed by rinsing with ultrapure water (UPW) and drying.

The semiconductor substrate is exposed to air during transfer to a rinse bath or a dryer for rinsing or drying, resulting in the formation of water marks on the surface of the gate conductive layers of p- and n-conductivity types. The water marks may cause lifting of the gate upon the subsequent gate patterning, and in some cases, they function as etching obstacles so that the gate conductive layers may remain unetched upon gate patterning.

### BRIEF SUMMARY OF THE INVENTION

Embodiments of the present invention are directed to a method for forming a dual gate of a semiconductor device by which photoresist patterns are removed without leaving any residue behind and no water mark is formed during cleaning for the removal of a native oxide layer.

In one embodiment, a method for forming a dual gate of a semiconductor device includes forming a first polysilicon layer doped with p-type impurity ions and a second polysilicon layer doped with n-type impurity ions on a first region and a second region of a semiconductor substrate, respectively; and sequentially subjecting the surfaces of the first and second polysilicon layers to first wet cleaning, second wet cleaning and dry cleaning.

In other embodiment, a method for forming a dual gate of a semiconductor device includes forming a first polysilicon layer doped with p-type impurity ions and a second polysilicon layer doped with n-type impurity ions on a first region and a second region of a semiconductor substrate, respectively; and sequentially subjecting the surfaces of the first and second polysilicon layers to wet cleaning, drying and dry cleaning.

In another embodiment, a method for forming a dual gate of a semiconductor device includes forming a first polysilicon layer doped with p-type impurity ions and a second polysilicon layer doped with n-type impurity ions on a first region and a second region of a semiconductor substrate, respectively; and sequentially subjecting the surfaces of the first and second polysilicon layers to first wet cleaning, second wet cleaning, third wet cleaning and dry cleaning

### BRIEF DESCRIPTION OF THE DRAWINGS FIGS. 1 to 9 are cross-sectional views illustrating a method for forming a dual gate of a semiconductor device according to an embodiment of the present invention;

FIG. 10 is a diagram showing the structure of a spin-type single cleaner used to remove photoresist residues in methods for forming a dual gate of a semiconductor device according to the present invention;

FIG. 11 is a flow chart illustrating a procedure for stripping of a photoresist in methods for forming a dual gate of a semiconductor device according to the present invention;

FIG. 12 is a flow chart illustrating another procedure for stripping of a photoresist in methods for forming a dual gate of a semiconductor device according to the present invention;

FIG. 13 is a flow chart illustrating a procedure for the removal of a native oxide layer in methods for forming a dual gate of a semiconductor device according to the present invention;

FIG. 14 is a flow chart illustrating another procedure for the removal of a native oxide layer in methods for forming a dual gate of a semiconductor device according to the present invention;

FIG. 15 is a flow chart illustrating another procedure for the removal of a native oxide layer in methods for forming a dual gate of a semiconductor device according to the present invention; and

FIG. 16 shows graphs illustrating a procedure for the removal of a native oxide layer in a method for forming a dual gate of a semiconductor device according to an embodiment of the present invention.

### DESCRIPTION OF SPECIFIC EMBODIMENTS

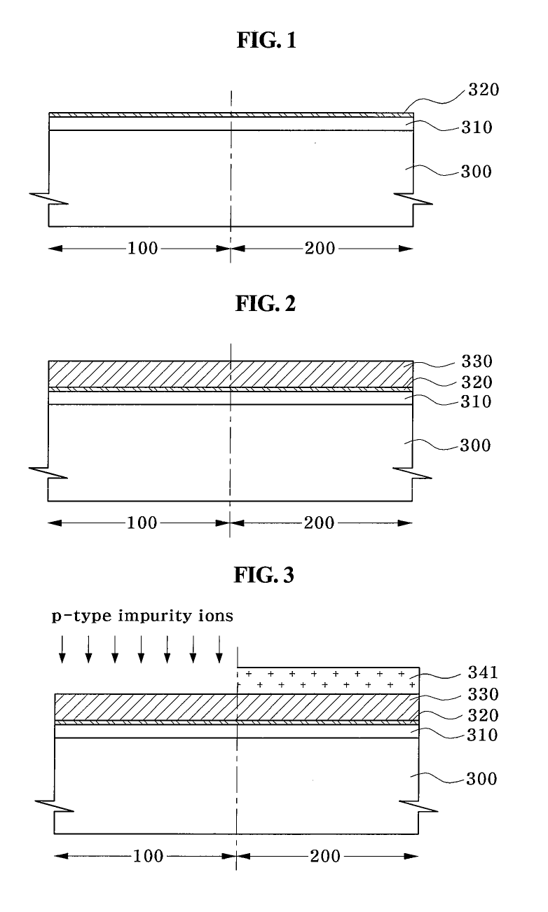

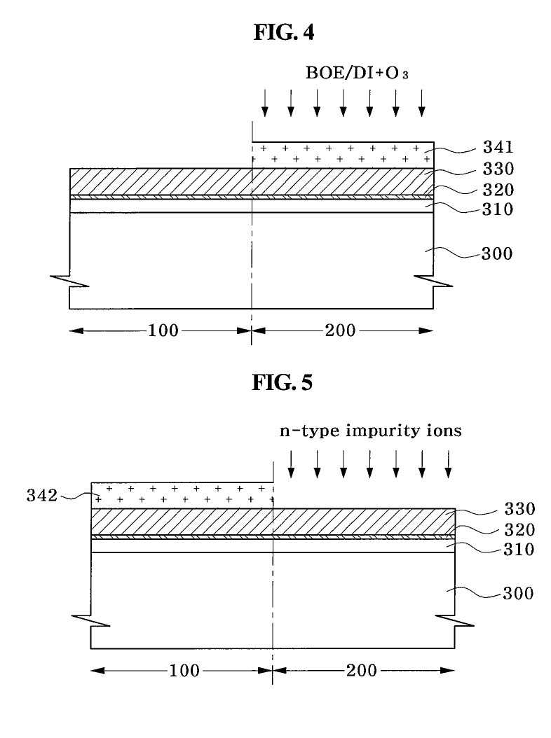

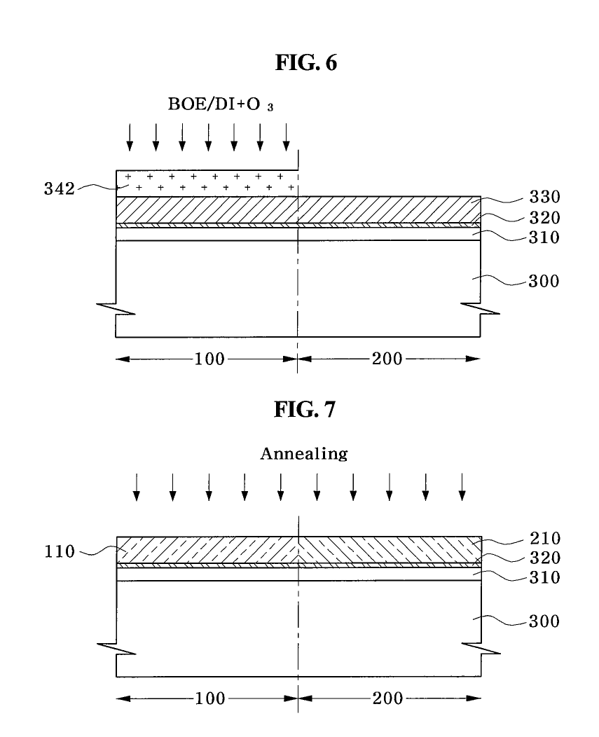

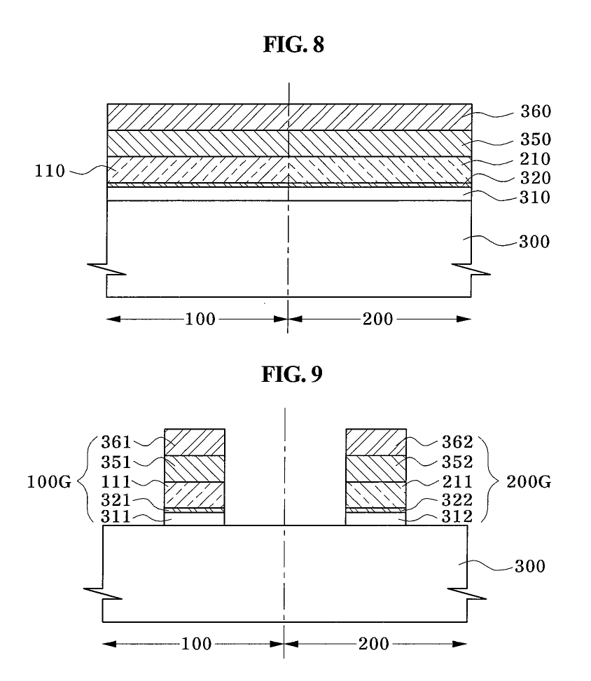

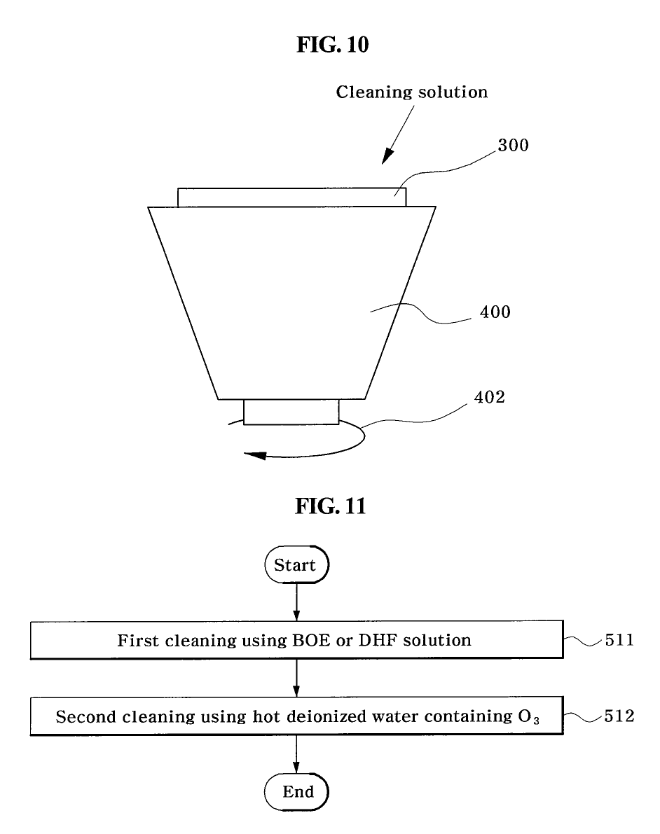

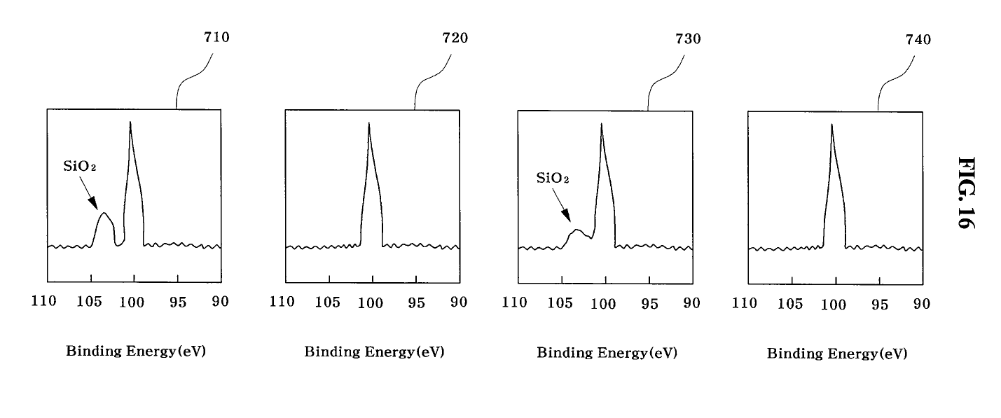

FIGS. 1 to 9 are cross-sectional views illustrating a method for forming a dual gate of a semiconductor device according to an embodiment of the present invention, FIG. 10 is a diagram showing the structure of a spin-type single cleaner used to remove photoresist residues in methods for forming a dual gate of a semiconductor device according to the present invention, and FIG. 16 shows graphs illustrating a procedure for the removal of a native oxide layer in a method for forming a dual gate of a semiconductor device according to an embodiment of the present invention.

With reference to FIG. 1, a gate insulating layer 310 is formed on a semiconductor substrate 300 having a first region 100 and a second region 200. The first region 100 is a region where a PMOS transistor is formed, and the second region 200 is a region where an NMOS transistor is formed. The semiconductor substrate 300 is a silicon substrate, but is not limited thereto. For example, the semiconductor substrate may be a silicon-on-insulator (SOI) substrate. The gate insulating layer 310 may be in the form of an oxide layer. The gate insulating layer 310 is subjected to plasma nitridation to form a nitride thin layer 320 on top of the gate insulating layer 310. The nitride layer 320 serves to inhibit p-type impurity ions (boron (B) ions) from penetrating the gate insulating layer 310 and entering the semiconductor substrate 300 in subsequent steps. Where necessary, the plasma nitridation may be omitted. The plasma nitridation may be performed using argon (Ar) and nitrogen (N₂) gases under a pressure of 400 mTorr at about 550° C. for about 70 seconds.

Referring to FIG. 2, a polysilicon layer 330 as a gate conductive layer is formed to a thickness of about 800 Åon the nitride layer 320. The polysilicon layer 330 may contain no impurity ions or may be doped with n-type impurity ions, such as phosphorus (P) ions. In latter case, the dose of the n-type impurity ions doped into the polysilicon layer 330 is about 2.0×10²⁰ ions/cm³.

Referring to FIG. 3, a first photoresist pattern 341 as a mask pattern is formed on a portion of the polysilicon layer 330 defined by the first region 200. The photoresist pattern 341 has an opening through which a portion of the polysilicon layer 330 defined by the first region 100 is exposed. As indicated by the arrows shown in the figure, ion implantation is performed using the first photoresist pattern 341 as a mask for ion implantation to implant p-type impurity ions into the exposed portion of the polysilicon layer 330. As a result, the p-type impurity ions are implanted into the portion of the polysilicon layer 330 defined by the first region 100. The implantation of the p-type impurity ions (e.g., boron (B) ions) can be performed by implanting the p-type impurity ions at a dose of about 1.5×10¹⁶ ions/cm² with an energy of about 5 keV.

After implantation of the p-type impurity ions is completed, stripping is performed to remove the first photoresist pattern 341, as shown in FIG. 4. This stripping is performed using a spin-type single cleaner. Specifically, the semiconductor substrate 300 is stably mounted on a rotating spinner 400 in the direction of the arrow 402 shown in FIG. 10, and then a cleaning solution is sprayed thereon. Since the spinner 400 is rotated at a high speed, the semiconductor substrate 300 is rotated at a high speed and hence the cleaning solution is uniformly distributed over the entire surface of the semiconductor substrate 300.

A procedure for stripping of the first photoresist pattern 341 is illustrated in FIG. 11. As shown in FIG. 11, the stripping is achieved through a series of first cleaning and second cleaning in the spin-type single cleaner shown in FIG. 10. First, first cleaning is performed using a BOE containing NH₄F (ca. 17 wt %) and HF (ca. 0.06 wt %) for about 30 seconds (step 511). The first cleaning may be performed using a diluted HF (DHF) solution. The first cleaning allows the surface of the first photoresist pattern 341 to be partially lift-off and causes lifting of the interface between the first photoresist pattern 341 and the polysilicon layer 330. After completion of the first cleaning, second cleaning is performed using hot deionized (DI) water containing O₃ for about 1 to about 30 minutes (step 512). The second cleaning is also performed in the spin-type single cleaner. The hot deionized (DI) water containing O₃ is controlled to have a temperature of 40 to 90° C. and an O₃ concentration of about 1% to about 10%. By the series of the first cleaning and the second cleaning, the first photoresist pattern 341 can be stripped without leaving any photoresist residue, which is demonstrated by Reaction 1 below:
—CH₂—+O₃→3O₂+CO₂+H₂O (1)

As depicted in Reaction 1, O₃ reacts with —CH₂, which is a constituent moiety of the photoresist, to generate 3O₂, CO₂ and H₂O, thus completing stripping the photoresist. This procedure is specifically depicted by Reactions 2 and 3 below:
O_{3→O}₂+O* (2)
3O* +—CH₂—CO₂+H₂O (3)

O₃ is decomposed to generate oxygen radicals O* as depicted in Reaction 2, and the oxygen radicals O* react with —CH₂— to generate CO₂ and H₂O as depicted in Reaction 3.

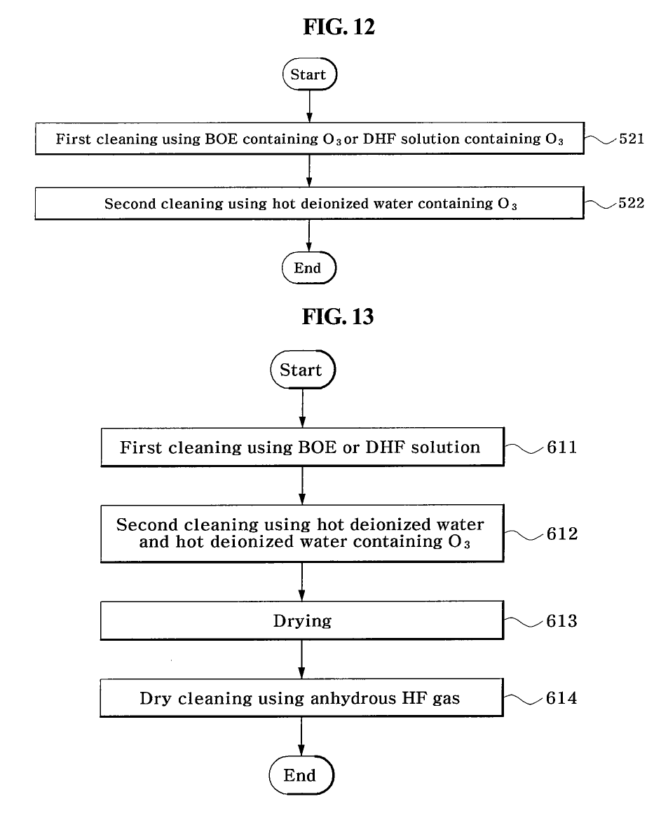

Another procedure for stripping of the first photoresist pattern 341 is illustrated in FIG. 12. As shown in FIG. 12, the stripping is achieved through a series of first cleaning and second cleaning in the spin-type single cleaner shown in FIG. 10. First, first cleaning is performed using a BOE containing O₃ (step 521). The first cleaning may be performed using a diluted HF (DHF) solution containing HF in a concentration of about 0.01 wt % to about 1 wt %. The first cleaning allows the surface of the first photoresist pattern 341 to be partially lift-off and causes lifting of the interface between the first photoresist pattern 341 and the polysilicon layer 330. After completion of the first cleaning, second cleaning is performed using hot deionized (DI) water containing O₃ in a concentration of about 1% to about 10% (step 522) for one minute to about 30 minutes. The hot deionized water is controlled to have a temperature of 40 to 90° C. The second cleaning is also performed in the spin-type single cleaner shown in FIG. 10. By the series of the first cleaning and the second cleaning, the first photoresist pattern 341 can be stripped without leaving any photoresist residue, which is already demonstrated by Reaction 1 above.

Referring to FIG. 5, a second photoresist pattern 342 as a mask pattern is formed on a portion of the polysilicon layer 330 from which the first photoresist pattern (341 in FIG. 4) is completely removed. The second photoresist pattern 342 has an opening through which a portion of the polysilicon layer 330 defined by the second region 200 is exposed. As indicated by the arrows shown in the figure, ion implantation is performed using the second photoresist pattern 342 as a mask for ion implantation to implant n-type impurity ions into the exposed portion of the polysilicon layer 330. As a result, the n-type impurity ions are implanted into the portion of the polysilicon layer 330 defined by the second region 200. The implantation of the n-type impurity ions (e.g., phosphorus (P) ions) can be performed by implanting the n-type impurity ions at a dose of about 1.5×10 ions/cm² with an energy of about 5 keV.

After implantation of the n-type impurity ions is completed, stripping is performed to remove the second photoresist pattern 342, as shown in FIG. 6. The stripping of the second photoresist layer pattern 342 can be performed in substantially the same manner as that of the first photoresist layer pattern (341 in FIG. 4), which is already explained with reference to FIGS. 11 and 12.

Referring to FIG. 7, annealing is performed on the polysilicon layer 330, into which the p- and n-type impurity ions are implanted, to activate the impurity ions. This annealing can be achieved by a rapid thermal process (RTP). The rapid thermal process is performed at about 950° C. for about 20 seconds. By the annealing, a first polysilicon layer 110 doped with the p-type impurity ions and a second polysilicon layer 210 doped with the n-type impurity ions are formed on portions defined by the first region 100 and the second region 200, respectively.

Next, cleaning is performed to remove a native oxide layer (not shown) formed on the surfaces of the first and second polysilicon layers 110 and 210. The cleaning is performed in the spin-type cleaner shown in FIG. 10. A procedure for the removal of the native oxide layer will be specifically explained with reference to FIG. 13. As shown in FIG. 13, wet cleaning is performed using BOE containing NH₄F (ca. 17 wt %) and HF (ca. 0.06 wt %) as a cleaning solution for about 10 to about 500 seconds (step 611). Optionally, a diluted HF solution containing HF in a concentration of about 0.1 wt % to about 5 wt % can be used together with the BOE. After completion of the first cleaning, additional cleaning is performed using hot deionized water and hot deionized water containing O₃ for about 3 minutes to form a new native oxide layer (not shown) having a predetermined thickness (e.g., 3 to 50 Å) on the first and second polysilicon layers 110 and 210 (step 612). For the cleaning, a HF solution containing HF in the concentration of about 0.1 wt % to about 5 wt % may be used instead of the hot deionized water containing O₃. Thereafter, drying is performed (step 613), followed by dry cleaning using anhydrous HF gas in a chamber-type cleaner to remove the native oxide layer (step 614). The temperature of a wafer is maintained at about 20° C. or less by controlling the temperature of the chamber-type cleaner during the dry cleaning. The final dry cleaning avoids the necessity for additional drying, thus preventing the formation of water marks.

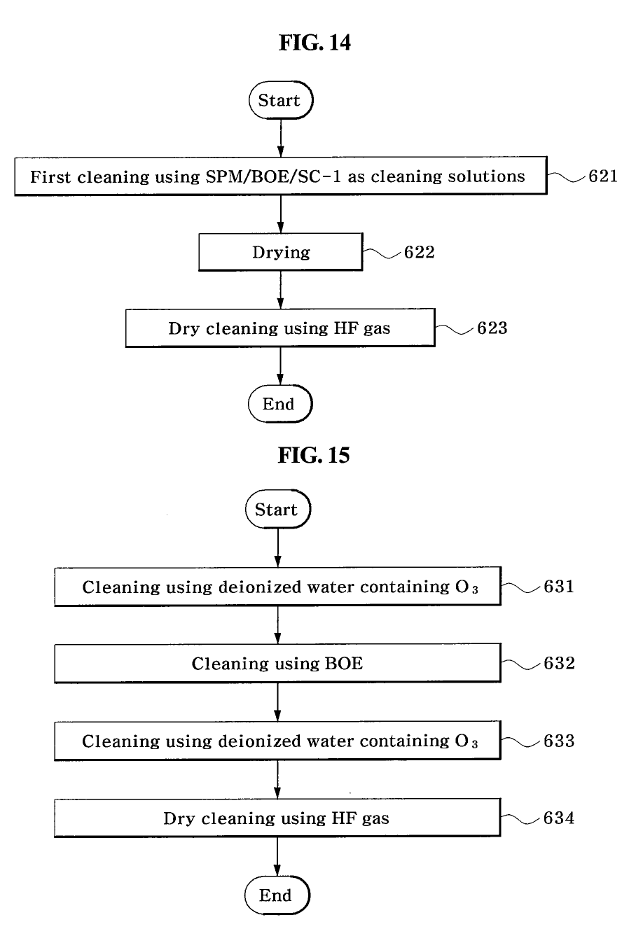

Another procedure for the removal of the native oxide layer will now be explained with reference to FIG. 14. As shown in FIG. 14, first, cleaning is performed sequentially using an SPM, a BOE and SC-1 as cleaning solutions (step 621). The SPM contains H₂SO₄ and H₂O₂ in a ratio of about 4:1 and is controlled to have a temperature of 120° C. The cleaning using the SPM is performed for about 5 minutes. The BOE contains NH₄F and HF in a ratio of about 17:0.06. The cleaning using the BOE is performed for about 200 seconds. The SC-1 contains NH₄OH, H₂O₂ and H₂O in a ratio of about 1:4 :20 and is controlled to have a temperature of 25° C. The cleaning using the SC-1 is performed for about 10 minutes. The cleaning (step 621) is performed in a batch-type cleaner. After the cleaning, drying is performed (step 622) and then dry cleaning is performed in a spin-type single cleaner using anhydrous HF gas to remove the native oxide layer (step 623).

Another procedure for the removal of the native oxide layer will now be explained with reference to FIG. 15. As shown in FIG. 15, first, cleaning using deionized water containing O₃ is performed for about 5 minutes (step 631). Next, cleaning is performed using a BOE containing NH₄F and HF in a ratio of about 17:0.06 for about 200 seconds (step 632). Again, cleaning is performed using deionized water containing O₃ for about 5 minutes (step 633). Finally, dry cleaning is performed using anhydrous HF gas (step 634).

FIG. 16 shows the analytical results of native oxide layers formed on the first and second polysilicon layers 110 and 210 at the respective cleaning steps by X-ray photoelectron spectroscopy (XPS). As shown in the graph indicated by numeral reference “710”, a native oxide (SiO₂) layer is present on the first and second polysilicon layers 110 and 210 before the cleaning. As shown in the graph indicated by numeral reference “720”, the native oxide layer is removed after the wet cleaning using the BOE, or the BOE and the diluted HF solution. As shown in the graph indicated by numeral reference “730”, a native oxide layer is newly formed by the cleaning using hot deionized water containing O₃. Finally, as shown in the graph indicated by numeral reference “740”, the native oxide layer is completely removed by the dry cleaning using anhydrous HF gas.

Referring to FIG. 8, a tungsten silicide layer 350 as a metal silicide layer and a hard mask nitride 360 as a gate hard mask are sequentially formed on the first and second polysilicon layers 110 and 210 from which the native oxide layer is removed. The tungsten silicide layer 350 can be formed using WF₆ and SiH₄ as reaction gases at about 350 to about 450° C. Alternatively, the tungsten silicide layer 350 can be formed using WF₆ and SiH₂Cl₂ as reaction gases at about 500 to about 600° C.

Referring to FIG. 9, the hard mask nitride, the tungsten silicide layer, the first and second polysilicon layers 110 and 210, the nitride 320 and the gate insulating layer 310 are patterned by a common technique to form a first gate stack 100G and a second gate stack 200G on the first region 100 and the second region 200 of the substrate 300, respectively. The first gate stack 100G consists of a first gate insulating layer pattern 311, a first nitride layer pattern 321, a first polysilicon layer pattern 111, a first tungsten silicide layer pattern 351 and a first hard mask nitride layer pattern 361 laminated in this order on the first region 100 of the substrate 300. The second gate stack 200G consists of a second gate insulating layer pattern 312, a second nitride layer pattern 322, a second polysilicon layer pattern 211, a second tungsten silicide layer pattern 352 and a second hard mask nitride layer pattern 362 laminated in this order on the second region 200 of the substrate 300.

Although the present invention has been described herein in detail with reference to its preferred embodiments, those skilled in the art will appreciate that these embodiments do not serve to limit the invention and that various changes and modifications may be made thereto without departing from the spirit and scope of the invention as defined in the appended claims.

What is claimed is:

1. A method for forming a dual gate of a semiconductor device, the method comprising the steps of:
forming a first polysilicon layer doped with p-type impurity ions and a second polysilicon layer doped with n-type impurity ions on a first region and a second region of a semiconductor substrate;
first wet cleaning the first and second polysilicon layers;
second wet cleaning the first and second polysilicon layers; and
dry cleaning the first and second polysilicon layers.

2. The method according to claim 1, wherein the step of forming the first and second polysilicon layers includes:
forming a gate insulating layer over the semiconductor substrate;
forming a polysilicon layer over the gate insulating layer;
forming a first photoresist pattern exposing the first polysilicon layer;
implanting p-type impurity ions into the exposed portion of the polysilicon layer;
removing the first photoresist pattern; and
forming a second photoresist pattern exposing the second polysilicon layer;
implanting n-type impurity ions into the exposed portion of the polysilicon layer;
removing the second photoresist pattern; and
annealing the first and second polysilicon layers.

3. The method according to claim 2, wherein the removing the first and second photoresist patterns include:
first cleaning the photoresist patterns using a buffered oxide etchant (BOE) as a first cleaning solution; and
second cleaning the photoresist patterns using deionized water containing O₃ as a second cleaning solution.

4. The method according to claim 3, wherein the BOE contains ozone (O₃).

5. The method according to claim 3, wherein the second cleaning is performed using deionized water containing O₃ in a concentration of about 1 to about 10% as a cleaning solution for about 1 to about 30 minutes while maintaining the temperature of the semiconductor substrate at about 40 to about 90° C.

6. The method according to claim 2, wherein the removing the first and second photoresist patterns include:
first cleaning the photoresist patterns using a diluted hydrofluoric acid (HF) solution as a first cleaning solution; and
second cleaning the photoresist patterns using deionized water containing O₃ as a second cleaning solution.

7. The method according to claim 6, wherein the diluted HF solution contains ozone (O₃).

8. The method according to claim 7, wherein the diluted HF solution contains HF in a concentration of about 0.01 to about 1 wt %.

9. The method according to claim 6, wherein the second cleaning is performed using deionized water containing O₃ in a concentration of about 1 to about 10% as a cleaning solution for about 1 to about 30 minutes while maintaining the temperature of the semiconductor substrate at about 40 to about 90° C.

10. The method according to claim 1, wherein the first wet cleaning is performed using a BOE as a cleaning solution for about 10 to about 500 seconds.

11. The method according to claim 1, wherein the first wet cleaning is performed using a BOE and a diluted HF solution as cleaning solutions.

12. The method according to claim 1, wherein the second wet cleaning is performed using deionized water containing O₃.

13. The method according to claim 1, wherein the second wet cleaning is performed using deionized water containing O₃ and a diluted HF solution containing O₃.

14. The method according to claim 1, wherein the first wet cleaning is performed to remove a native oxide layer formed on the first and second polysilicon layers, the second wet cleaning is performed to form a new native oxide layer on the first and second polysilicon layers, and the dry cleaning is performed to remove the native oxide layer formed after the second wet cleaning.

15. The method according to claim 14, wherein the native oxide layer formed after the second wet cleaning has a thickness of about 3 to about 50 Å.

16. The method according to claim 1, wherein the dry cleaning is performed using anhydrous HF gas.

17. The method according to claim 16, wherein the dry cleaning using anhydrous HF gas is performed while maintaining the temperature of the semiconductor substrate at about 20° C. or less.

18. The method according to claim 1, further comprising the step of drying after the second wet cleaning.

19. A method for forming a dual gate of a semiconductor device, the method comprising the steps of:
forming a first polysilicon layer doped with p-type impurity ions and a second polysilicon layer doped with n-type impurity ions on a first region and a second region of a semiconductor substrate, respectively; and
wet cleaning the first and second polysilicon layers;
drying the first and second polysilicon layers; and
dry cleaning the first and second polysilicon layers.

20. The method according to claim 19, wherein the wet cleaning is performed using a sulfuric acid peroxide mixture (SPM), a BOE and Standard Clean-1 (SC-1) as cleaning solutions.

21. The method according to claim 19, wherein the wet cleaning is performed in a batch-type cleaner.

22. The method according to claim 19, wherein the dry cleaning is performed using anhydrous HF gas.

23. The method according to claim 19, wherein the dry cleaning is performed in a spin-type single cleaner.

24. A method for forming a dual gate of a semiconductor device, the method comprising the steps of:
forming a first polysilicon layer doped with p-type impurity ions and a second polysilicon layer doped with n-type impurity ions on a first region and a second region of a semiconductor substrate, respectively; and
first wet cleaning the first and second polysilicon layers;
second wet cleaning the first and second polysilicon layers;
third wet cleaning the first and second polysilicon layers; and
dry cleaning the first and second polysilicon layers.

25. The method according to claim 24, wherein the first wet cleaning is performed using deionized water containing O₃.

26. The method according to claim 24, wherein the second wet cleaning is performed using a BOE as a cleaning solution.

27. The method according to claim 24, wherein the third wet cleaning is performed using deionized water containing O₃.

28. The method according to claim 24, wherein the dry cleaning is performed using anhydrous HF gas.
